(19) United States
(12) Patent Application Publication
(10) Pub. No.: US 2018/0179663 A1
(43) Pub. Date: Jun. 28, 2018

(54) VAPOR PHASE GROWTH APPARATUS AND VAPOR PHASE GROWTH METHOD

(71) Applicant: NuFlare Technology, Inc., Kanagawa (JP)

(72) Inventors: Hideshi TAKAHASHI, Yokohama-shi (JP); Yuusuke SATO, Tokyo (JP)

(21) Appl. No.: 15/850,164

(22) Filed: Dec. 21, 2017

(30) Foreign Application Priority Data
Dec. 22, 2016 (JP) 2016-248714

(51) Int. Cl. C30B 25/16; C30B 29/40; C30B 25/18

(52) U.S. Cl. CPC C30B 25/16; C30B 25/183; C30B 29/406

(57) ABSTRACT

A vapor phase growth apparatus according to an embodiment includes: a reactor; a supporter provided in the reactor, a substrate being capable of being placed on the supporter; a heater heating the substrate; a warpage measurement device measuring warpage of the substrate; a controller determining whether the measured warpage or a rate of change in the warpage is greater than a threshold value of the warpage or the rate of change in the warpage and stopping the heater on the basis of a determination result, the threshold value being stored in advance; a supplier supplying a process gas to the reactor; and an exhaust exhausting an exhaust gas from the reactor.

### CROSS-REFERENCE TO RELATED APPLICATION

This application is based upon and claims the benefit of priority from Japanese Patent Applications No. 2016-248714, filed on Dec. 22, 2016, the entire contents of which are incorporated herein by reference.

### FIELD OF THE INVENTION

Embodiments described herein relate generally to a vapor phase growth apparatus and a vapor phase growth method.

### BACKGROUND OF THE INVENTION

As a method for forming a high-quality semiconductor film, there is an epitaxial growth technique which grows a single-crystal film on a substrate (wafer), using vapor phase growth.

In a vapor phase growth method and a vapor phase growth apparatus using the epitaxial growth technique, a substrate is supported by a supporter in a reactor which is maintained at normal pressure or reduced pressure and is heated. Then, reaction gas which is a raw material for forming a film is supplied onto the substrate. For example, the thermal reaction of reaction gas occurs in the surface of the substrate and an epitaxial single-crystal film is formed on the surface of the substrate.

### SUMMARY OF THE INVENTION

When there is a large difference between a lattice constant of a material of the substrate and a lattice constant of a material of a film formed on the substrate, warpage is likely to occur in the substrate during deposition. When it is difficult to control the warpage, the film is likely to crack.

When the warped substrate is used, the substrate is broken or peels off and the inside of a reaction furnace is contaminated. As a result, maintenance is required and an operating ratio is reduced.

An object of the invention is to provide a vapor phase growth apparatus and a vapor phase growth method that can improve an operating ratio.

A vapor phase growth apparatus according to an aspect of the invention includes: a reactor; a supporter provided in the reactor, a substrate being capable of being placed on the supporter; a heater heating the substrate; a warpage measurement device measuring warpage of the substrate; a controller determining whether the measured warpage or a rate of change in the warpage is greater than a threshold value of the warpage or the rate of change in the warpage and stopping the heater on the basis of a determination result, the threshold value being stored in advance; a supplier supplying a process gas to the reactor; and an exhausting an exhaust gas from the reactor.

A vapor phase growth method according to another aspect of the invention includes: placing a substrate on a supporter provided in a reactor; heating the substrate; supplying a process gas to the reactor; measuring warpage of the substrate; and stopping the heating when the measured warpage or a rate of change in the warpage is greater than a threshold value of the warpage or a threshold value of the rate of change in the warpage, the threshold value being stored in advance.

### BRIEF DESCRIPTION OF THE DRAWINGS

FIG. 1 is a diagram schematically illustrating a vapor phase growth apparatus unit according to an embodiment;

FIG. 2 is a diagram schematically illustrating a reactor according to the invention;

FIG. 3 is a flowchart illustrating a vapor phase growth method according to the embodiment; and

FIGS. 4A and 4B are diagrams schematically illustrating a change in the warpage of a silicon substrate on which a film is formed by the vapor phase growth apparatus according to the embodiment.

### DETAILED DESCRIPTION OF THE EMBODIMENTS

### Embodiment

Hereinafter, an embodiment of the invention will be described with reference to the drawings.

In the specification, the direction of gravity in a state in which a vapor phase growth apparatus is provided so as to form a film is defined as a “lower” direction and a direction opposite to the direction of gravity is defined as an “upper” direction. Therefore, a “lower portion” means a position in the direction of gravity relative to the reference and a “lower side” means the direction of gravity relative to the reference. In addition, an “upper portion” means a position in the direction opposite to the direction of gravity relative to the reference and an “upper side” means the direction opposite to the direction of gravity relative to the reference. Furthermore, a “longitudinal direction” is the direction of gravity.

In the specification, “process gas” is a general term of gas used to form a film on a substrate. The concept of the “process gas” includes, for example, source gas and carrier gas.

A vapor phase growth apparatus according to this embodiment includes: a reactor; a supporter which is provided in the reactor and on which a substrate is capable of being placed; a heater that heats the substrate; a warpage measurement device that measures warpage of the substrate; a controller that determines whether the measured warpage or a rate of change in the warpage is greater than a threshold value of the warpage or the rate of change in the warpage which is stored in advance and stops the heater on the basis of a determination result; a supplier that supplies a process gas to the reactor; and an exhaust that exhausts an exhaust gas from the reactor.

A vapor phase growth method according to this embodiment includes: placing a substrate on a supporter provided in a reactor; heating the substrate; supplying a process gas to the reactor; measuring warpage of the substrate; and stopping the heating when the measured warpage or a rate of change in the warpage is greater than a threshold value of the warpage or a threshold value of the rate of change in the warpage which is stored in advance.

According to the vapor phase growth apparatus and the vapor phase growth method of this embodiment, it is possible to detect the breaking of a substrate or the peeling-off of a film formed on the substrate in advance and to improve the operating ratio of the vapor phase growth apparatus.

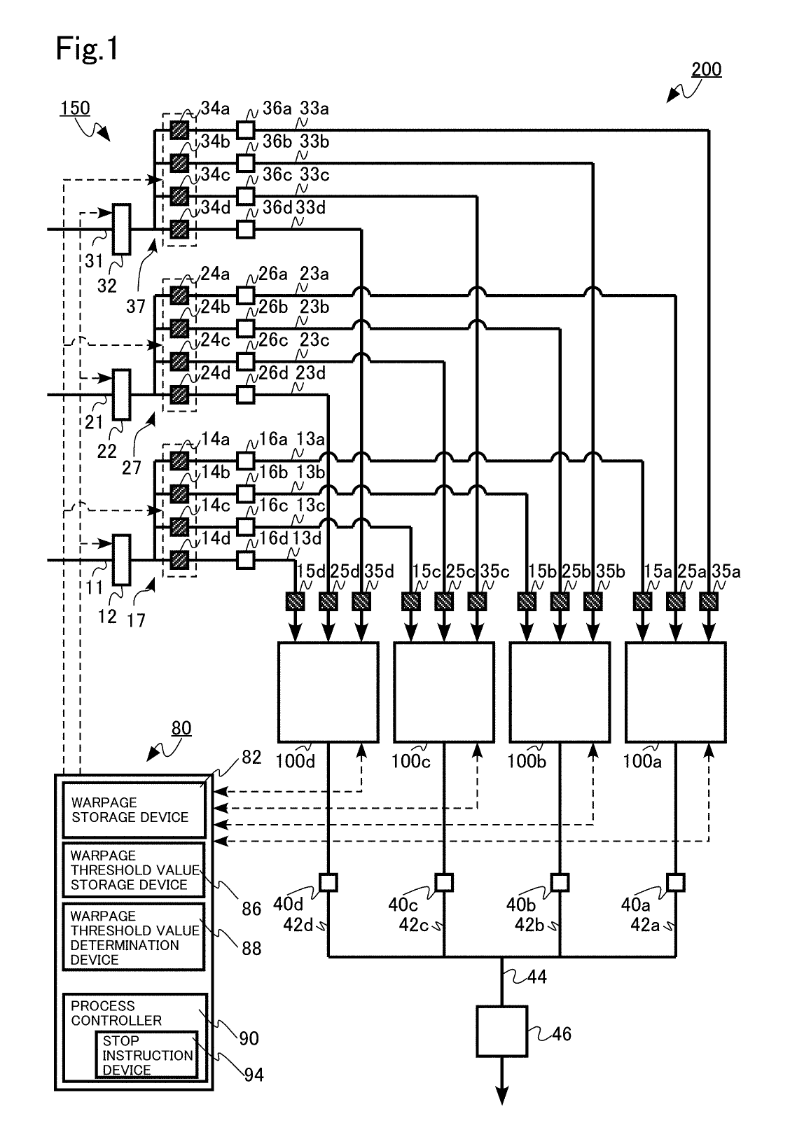

FIG. 1 is a diagram schematically illustrating a vapor phase growth apparatus unit 200 according to this embodiment. The vapor phase growth apparatus unit 200 according to this embodiment is, for example, an epitaxial growth apparatus using a metal organic chemical vapor deposition method (MOCVD method). Hereinafter, an example in which gallium nitride (GaN) is epitaxially grown will be mainly described.

The vapor phase growth apparatus unit 200 according to this embodiment includes four vapor phase growth apparatuses 100a, 100b, 100c and 100d. Hereinafter, in some cases, “100a, 100b, 100c, and 100d” is represented by “100a to 100d”.

Each of the four vapor phase growth apparatuses 100a to 100d is, for example, a vertical single wafer type epitaxial growth apparatus. Epitaxial growth is performed in each of four reactors 10a to 10d provided in each of the four vapor phase growth apparatuses 100a to 100d. The number of vapor phase growth apparatuses is not limited to 4 and may be an arbitrary value. The number of vapor phase growth apparatuses can be represented by n (n is an integer).

In addition, the vapor phase growth apparatus unit 200 includes a supplier 150 that supplies process gas. The supplier 150 includes a first main gas supply path 11, a first main mass flow controller 12, first to fourth sub-gas supply paths 13a to 13d, first stop valves 14a to 14d, second stop valves 15a to 15d, sub-mass flow controllers 16a to 16d, a branch portion 17, a second main gas supply path 21, a second main mass flow controller 22, first to fourth sub-gas supply paths 23a to 23d, first stop valves 24a to 24d, second stop valves 25a to 25d, sub-mass flow controllers 26a to 26d, a branch portion 27, a third main gas supply path 31, a third main mass flow controller 32, first to fourth sub-gas supply paths 33a to 33d, first stop valves 34a to 34d, second stop valves 35a to 35d, sub-mass flow controllers 36a to 36d, and a branch portion 37.

The first main gas supply path 11 supplies, for example, the first process gas including organic metal source gas, which is a group-III element gas, and carrier gas to each of the vapor phase growth apparatuses 100a to 100d. The first process gas supplies a group-III element used to form a group III-V semiconductor film on a substrate.

The group-III element is, for example, gallium (Ga), aluminum (Al), or indium (In). In addition, the organic metal is, for example, trimethylgallium (TMG), trimethylaluminum (TMA), or trimethylindium (TMI). Gas including TMG is a source gas of Ga. Gas including TMA is a source gas of Al. In addition, gas including TMI is a source gas of In.

The carrier gas is, for example, hydrogen gas. Only hydrogen gas may flow through the first main gas supply path 11.

The first main mass flow controller 12 is provided in the first main gas supply path 11. The first main mass flow controller 12 controls the flow rate of a first process gas through the first main gas supply path 11.

In addition, the branch portion 17 that branches the first main gas supply path 11 is provided. The first main gas supply path 11 is branched into four first sub-gas supply paths, that is, the first sub-gas supply path 13a, the second sub-gas supply path 13b, the third sub-gas supply path 13c, and the fourth sub-gas supply path 13d by the branch portion 17 at a position that is closer to the vapor phase growth apparatuses 100a to 100d than to the first main mass flow controller 12. The first sub-gas supply path 13a, the second sub-gas supply path 13b, the third sub-gas supply path 13c, and the fourth sub-gas supply path 13d supply the branched first process gas to the four vapor phase growth apparatuses 100a to 100d, respectively.

The first stop valves 14a to 14d that can stop the flow of the first process gas are provided in the four sub-gas supply paths 13a to 13d. When a failure occurs in any one of the four vapor phase growth apparatuses 100a to 100d, the first stop valves 14a to 14d have a function of instantaneously stopping the flow of the process gas to the vapor phase growth apparatus in which the failure has occurred.

The first stop valves 14a to 14d are provided between the branch portion 17 and the four vapor phase growth apparatuses 100a to 100d, respectively. The first stop valves 14a to 14d are disposed such that the distance to the branch portion 17 is less than the distance to the vapor phase growth apparatuses 100a to 100d.

It is preferable that the first stop valves 14a to 14d be provided so as to be adjacent to the branch portion 17. It is more preferable that the distance between the branch portion 17 and the first stop valves 14a to 14d be equal to or greater than 20 cm and equal to or less than 30 cm.

The four second stop valves 15a to 15d that can stop the flow of the first process gas are provided between the four first stop valves 14a to 14d in the four sub-gas supply paths 13a to 13d and the four vapor phase growth apparatuses 100a to 100d. For example, the second stop valves 15a to 15d are closed when the vapor phase growth apparatuses 100a to 100d are open to the air for maintenance and stop the upstream side from being open. to the air. The second stop valves 15a to 15d are provided at positions close to the vapor phase growth apparatuses 100a to 100d.

The four sub-mass flow controllers 16a to 16d that control the flow rate of the first process gas through the four sub-gas supply paths 13a to 13d are provided between the four first stop valves 14a to 14d and the four second stop valves 15a to 15d provided in the four sub-gas supply paths 13a to 13d.

When the vapor phase growth apparatuses 100a to 100d are open to the air, it is preferable that the second stop valves 15a to 15d be provided between the sub-mass flow controllers 16a to 16d and the vapor phase growth apparatuses 100a to 100d in order to prevent the four sub-mass flow controllers 16a to 16d from being exposed to the air.

The second main gas supply path 21 supplies the second process gas that does not include source gas, such as hydrogen gas or inert gas, to the vapor phase growth apparatuses 100a to 100d.

Only hydrogen gas may flow through the second main gas supply path 21.

The second main mass flow controller 22 is provided in the second main gas supply path 21. The second main mass flow controller 22 controls the flow rate of the second process gas through the second main gas supply path 21.

The branch portion 27, the sub-gas supply paths 23a to 23d, the first stop valves 24a to 24d, the second stop valves 25a to 25d, and the sub-mass flow controllers 26a to 26d are connected to the second main gas supply path 21. Since the components have the same configuration and function as the branch port on 17, the sub-gas supply paths 13a to 13d, the first stop valves 14a to 14d, the second stop valves 15a to 15d, and the sub-mass flow controllers 16a to 16d connected to the first main gas supply path 11, the description thereof will not be repeated.

The third main gas supply path 31 supplies, for example, the third process gas including ammonia to the vapor phase growth apparatuses 100a to 100d. The third process gas supplies nitrogen (N) which is a group-V element when a group III-V semiconductor film is formed on the substrate.

Only hydrogen gas may flow through the third main gas supply path 31.

The third main mass flow controller 32 is provided in the third main gas supply path 31. The third main mass flow controller 32 controls the flow rate of the third process gas through the third main gas supply path 31.

The branch portion 37, the sub-gas supply paths 33a to 33d, the first stop valves 34a to 34d, the second stop valves 35a to 35d, and the sub-mass flow controllers 36a to 36d are connected to the third main gas supply path 31. Since the components have the same configuration and function as the branch portion 17, the sub-gas supply paths 13a to 13d, the First stop valves 14a to 14d, the second stop valves 15a to 15d, and the sub-mass flow controllers 16a to 16d connected to the first main gas supply path 11, the description thereof will not be repeated.

The vapor phase growth apparatus unit 200 according to this embodiment includes four sub-gas exhaust paths 42a to 42d through which gas is exhausted from the four vapor phase growth apparatuses 100a to 100d. The vapor phase growth apparatus unit 200 includes a main gas exhaust path 44 where the four sub-gas exhaust paths 42a to 42d are joined. In addition, an exhaust 46 for sucking gas is provided in the main gas exhaust path 44. The exhaust 46 is, for example, a known vacuum pump.

Pressure adjustment portions 40a to 40d are provided in the four sub-gas exhaust paths 42a to 42d, respectively. The pressure adjustment portions 40a to 40d control the internal pressure of the vapor phase growth apparatuses 100a to 100d such that the internal pressure is a predetermined value. The pressure adjustment portions 40a to 40d are, for example, throttle valves. Instead of the pressure adjustment portions 40a to 40d, one pressure adjustment portion may be provided in the main gas exhaust path 44.

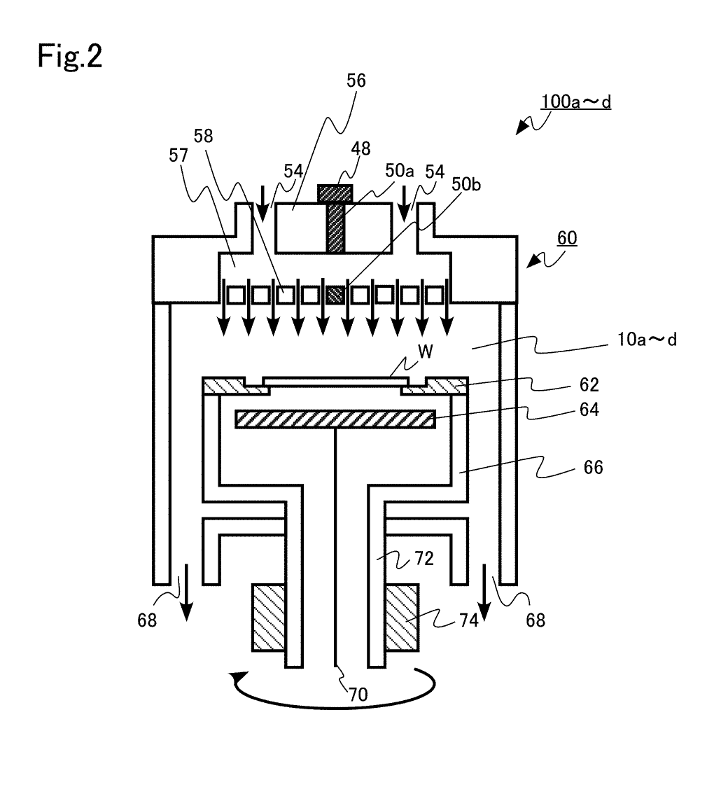

FIG. 2 is a diagram schematically illustrating the vapor phase growth apparatuses 100a to 100d according to the embodiment. The vapor phase growth apparatuses 100a to 100d include reactors 10a to 10d. Shower heads 60 that supply the process gas into the reactors 10a to 10d are provided in upper parts of the reactors 10a to 10d. The shower head 60 includes a shower plate 58, a mixing chamber 57 that is provided above the shower plate 58, and a top plate 56 that is provided above the mixing chamber 57. The supplier 150 may supply the predetermined amount of process gas to each of the reactors from a unified gas supply source, wherein the unified gas supply source includes a first process gas source supplying a first process gas, a second process gas source supplying a second process gas, and a third process gas source supplying a third process gas.

Gas supply portions 54 for supplying the process gas into the reactors 10a to 10d are provided in the top plates 56. The gas supply portions 54 are connected to the second stop valves 15a to 15d, the second stop valves 25a to 25d, and the second stop valves 35a to 35d.

The process gas supplied from the gas supply portion 54 is mixed in the mixing chamber 57. Then, the process gas is supplied to the reactors 10a to 10d through the shower plates 58.

A warpage measurement mechanism 48 is provided above the top plate 56. The warpage measurement mechanism 48 is, for example, a measurement device that measures the warpage of the substrate W using a laser.

A first transparent member 50a is provided in the top plate 56 and a second transparent member 50b is provided in the shower plate 58. The first transparent member 50a and the second transparent member 50b transmit laser light that is emitted from the warpage measurement mechanism 48 and light reflected from the substrate W.

The first transparent member 50a and the second transparent member 50b need to pass through the top plate 56 and the shower plate 58 respectively in order to transmit the laser light with high efficiency such that the substrate W is irradiated with the laser light and to detect the reflection with high efficiency.

The first transparent member 50a and the second transparent member 50b are sufficiently transparent with respect to a predetermined wavelength used for the warpage measurement mechanism 48 and is, for example, quartz glass. In addition, for example, sapphire can be used as long as it has sufficient strength, is sufficiently transparent with respect to a predetermined wavelength, and has high resistance to the process gas.

A supporter 62 on which the substrate W can be placed is provided below the shower head 60 in each of the reactors 10a to 10d. The supporter 62 may be, for example, a ring-shaped holder that has an opening at the center as illustrated in FIG. 2 or a susceptor having a structure that comes into contact with substantially the entire rear surface of the substrate W.

A rotating unit 66 that has an upper surface on which the supporter 62 is disposed and rotates the supporter 62 is provided. In addition, a heater as a heater 64 that heats the substrate W placed on the supporter 62 is provided below the supporter 62.

A rotating shaft 72 of the rotating unit 66 is connected to a rotating mechanism 74 that is provided in a lower part of the rotating shaft 72. The rotating mechanism 74 can rotate the substrate W on its center at a speed that is, for example, equal to or greater than 50 rpm and equal to or less than 2000 rpm.

A vacuum sealing member is interposed between the rotating shaft 72 and the bottom of each of the reactors 10a to 10d.

The heater 64 is provided so as to be fixed in the rotating unit 66. Power is supplied to the heater 64 through an electrode 70 that passes through the rotating shaft 72. In addition, a push up pin (not illustrated) that passes through the heater 64 is provided in order to attach and detach the substrate W to and from the supporter 62.

Furthermore, gas exhaust portions 68 which exhaust a reaction product obtained by the reaction of the source gas on, for example, the surface of the substrate W and an unreacted process gas to the outside of the reactors 10a to 10d are provided at the bottoms of the reactors 10a to 10d. In addition, the gas exhaust portions 68 are connected to the pressure adjustment portions 40a to 40d.

Substrate loading/unloading ports and gate valves (not illustrated) through which the substrate is transferred are provided. The substrate W can be transferred between load lock chambers (not illustrated) and the reactors 10a to 10d which are connected to each other by the gate valves by a handling arm. Here, for example, the handling arm made of synthetic quartz can be inserted into a space between the shower head 60 and the supporter 62.

A controller 80 includes a warpage storage device 82, a warpage threshold value storage unit 86, a warpage threshold value determination device 88, a process controller 90, and a stop instruction device 94.

The warpage storage device 82 stores the warpage of the first to fourth substrates W and/or the rate of change in the warpage measured by the warpage measurement mechanisms 48. For example, the controller 80 can calculate the rate of change in the warpage, using a change in the warpage stored in the warpage storage device 82 over time.

The warpage threshold value storage device 86 stores a threshold value of the warpage and/or a threshold value of the rate of change in the warpage of the first to fourth substrates W.

The warpage threshold value determination device 88 determines whether the warpage and/or the rate of change in the warpage of the first to fourth substrates W stored in the warpage storage device 82 is greater than the threshold value.

The controller 80 includes a process controller 90 and controls the main mass flow controllers 12, 22, and 32, the sub-mass flow controllers 16a to 16d, 26a to 26d, and 36a to 36d, the first stop valves 14a to 14d, 24a to 24d, and 34a to 34d, the second stop valves 15a to 15d, 25a to 25d, and 35a to 35d, and the pressure adjustment portions 40a to 40d. In addition, the process controller 90 controls a series of processes, such as the rotation and stop of the substrate W by the rotating mechanism 74, the exhaust of the process gas and the residual gas by the exhaust 46, the loading and unloading of the first to fourth substrates W to and from the reactors 10a to 10d by the handling arm, and the placement of the first to fourth substrates W on the supporters 62.

In addition, the process controller 90 controls the vapor phase growth conditions of the four reactors 10a to 10d at the same time such that the vapor phase growth conditions are the same.

The process controller 90 includes the stop instruction device 94. When the warpage and/or the rate of change in the warpage is greater than the threshold value, the process controller 90 stops the heating of the substrate W by the heater 64 in any one of the four reactors 10a to 10d.

The controller 80 is, for example, an electronic circuit. The controller 80 is, for example, a computer which is a combination of hardware, such as an arithmetic circuit, and software, such as a program.

In addition, the controller 80 may be hardware, such as an electric circuit or a quantum circuit, or software. When the controller 80 is software, a microprocessor, such as a central processing unit (CPU), a read only memory (ROM) that stores a processing program, a random access memory (RAM) that temporarily stores data, an input/output port, and a communication port may be used. A recording medium is not limited to a detachable recording medium, such as a magnetic disk or an optical disk, and may be a fixed recording medium, such as a hard disk device or a memory.

The warpage storage device 82 and the warpage threshold value storage device 86 are, for example, storage devices. The storage device is, for example, a semiconductor memory or a hard disk.

The warpage threshold value determination device 88, the process controller 90, and the stop instruction device 94 are, for example, electronic circuits.

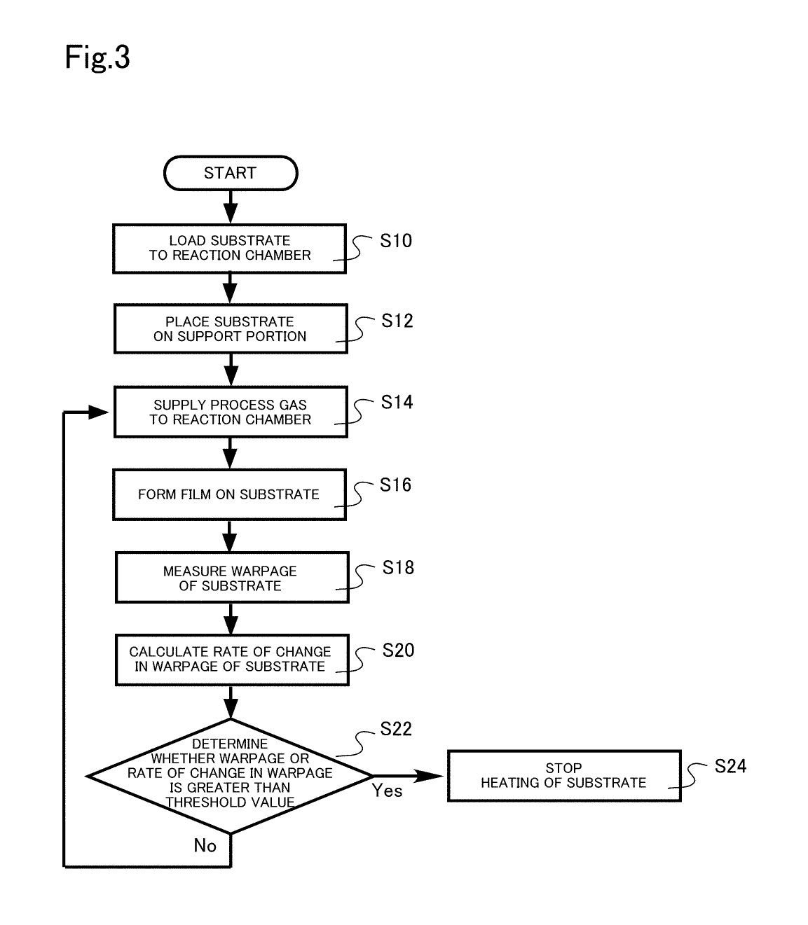

FIG. 3 is a flowchart illustrating the vapor phase growth method according to this embodiment.

Hereinafter, an example in which GaN is epitaxially grown on a substrate by the vapor phase growth method according to this embodiment will be described.

First, the first to fourth substrates are loaded to the reactors 10a to 10d, respectively (S10). Each of the first to fourth substrates is, for example, a silicon (Si) wafer.

When the substrates are loaded, for example, the gate valves (not illustrated) in the substrate loading/unloading ports of the reactors 10a to 10d are opened and the first to fourth substrates W in the load lock chambers (not illustrated) are transferred into the reactors 10a to 10d by the handling arm (not illustrated).

Then, the first to fourth substrates W are placed on the supporters 62 provided in the reactors 10a to 10d (S12).

For example, the first to fourth substrates W are placed on the supporters 62 by the push up pins (not illustrated). The handling arm is returned to the load lock chamber and the gate valve is closed.

Then, the gas in the reactors 10a to 10d is exhausted from the sub-gas exhaust paths 42a to 42d and the main gas exhaust path 44 by the exhaust 46 and the internal pressure of the reactors 10a to 10d is changed to a predetermined pressure by the pressure adjustment portions 40a to 40d. Here, the heating power of the heater 64 is increased and the temperature of the first to fourth substrates W is maintained at a preliminary heating temperature.

Then, the heating power of the heater 64 is increased to raise the temperature of the first to fourth substrates W to a baking temperature that is, for example, equal to or greater than 1000° C. and equal to or less than 1100° C. The temperature of the substrates can be measured by, for example, a radiation thermometer.

Then, the heating power of the heater 64 is controlled such that the temperature of the first to fourth substrates W is adjusted to an epitaxial growth temperature while the first to fourth substrates W are rotated at a predetermined rotational speed by the rotating units 66.

Then, the process gas is supplied into the reactors 10a to 10d (S14) and films are formed on the first to fourth substrates W (S16).

Then, the warpage of the first to fourth substrates W is measured by the warpage measurement mechanism 48 (S18). The measured warpage is stored in the warpage storage device 82.

In this case, the rate of change in the warpage of the first to fourth substrates may be calculated, using the warpage of the first to fourth substrates, and then stored (S20). Both the calculated rate of change in the warpage and the warpage may be stored in the warpage storage device 82.

Then, the warpage threshold value determination device 88 determines whether the measured warpage of the first to fourth substrates and/or the measured rate of change in the warpage stored in the warpage storage device 82 is greater than the threshold value, using the threshold value stored in the warpage threshold value storage device 86 (S22).

When the measured warpage of one of the first to fourth substrates or the measured rate of change in the warpage is equal to or greater than the threshold value, the stop instruction device 94 stops the heater 64 used to heat the substrate of which the measured warpage or the measured rate of change in the warpage is equal to or greater than the threshold value. Then, the heating of the substrate of which the measured warpage or the measured rate of change in the warpage is equal to or greater than the threshold value is stopped (S24).

Then, the process returns to S14 and the process gas is supplied into the reactors 10a to 10d to form films on the substrates other than the substrate W that has been stopped from being heated (S16). Then, the process from S14 to S22 is repeated until the formation of films is completed and heating is stopped at the time warpage occurs. Then, when warpage occurs in all of the substrates W, the supply of the process gas to all of the reactors 10a to 10d is stopped.

An example of the operation performed in S14 and S16 is as follows.

The heating power of the heater 64 is adjusted such that the temperature of the first to fourth substrates W is an epitaxial growth temperature that is, for example, equal to or greater than 950° C. and equal to or less than 1050° C.

Then, gas including TMA which has hydrogen gas as carrier gas is supplied from the first main gas supply path 11 to the reactors 10a to 10d, gas including hydrogen is supplied from the second main gas supply path 21 to the reactors 10a to 10d, and gas including ammonia is supplied from the third main gas supply path 31 to the reactors 10a to 10d.

The flow rate of the gas including TMA which has hydrogen gas as carrier gas is controlled by the first main mass flow controller 12 and the gas is branched and supplied to the four sub-gas supply paths 13a to 13d branched from the first main gas supply path 11.

The flow rate of the gas including hydrogen is controlled by the second main mass flow controller 22 and the gas is branched and supplied to the four sub-gas supply paths 23a to 23d branched from the second main gas supply path 21.

The flow rate of the gas including ammonia is controlled by the third main mass flow controller 32 and the gas is branched and supplied to the four sub-gas supply paths 33a to 33d branched from the third main gas supply path 31.

In this way, aluminum nitride (AlN) films are grown on the first to fourth substrates. The thickness of the AlN film is, for example, equal to or greater than 100 nm and equal to or less than 300 nm. In addition, monosilane (SiH₄) and ammonia may be supplied to grow a silicon nitride (SiN) layer below the AlN film.

Then, gas including TMA and TMG which have hydrogen gas as carrier gas is supplied from the first main gas supply path 11 to the reactors 10a to 10d, gas including hydrogen is supplied from the second main gas supply path 21 to the reactors 10a to 10d, and gas including ammonia is supplied from the third main gas supply path 31 to the reactors 10a to 10d.

In this way, aluminum gallium nitride (AlGaN) films are grown on the first to fourth substrates.

Then, gas including TMG which have hydrogen gas as carrier gas is supplied from the first main gas supply path 11 to the reactors 10a to 10d, gas including hydrogen is supplied from the second main gas supply path 21 to the reactors 10a to 10d, and gas including ammonia (NH₃) is supplied from the third main gas supply path 31 to the reactors 10a to 10d.

In this way, GaN films are formed on the first to fourth substrates W.

When the formation of the films is completed, the supply of the process gas from the first main gas supply path 11 and the third main gas supply path 31 is stopped and the heating power of the heater 64 is decreased to reduce the temperature of the first to fourth substrates to a transferring temperature.

Then, the first to fourth substrates are unloaded from the reactors 10a to 10d.

The threshold value may change depending on the type of film to be formed.

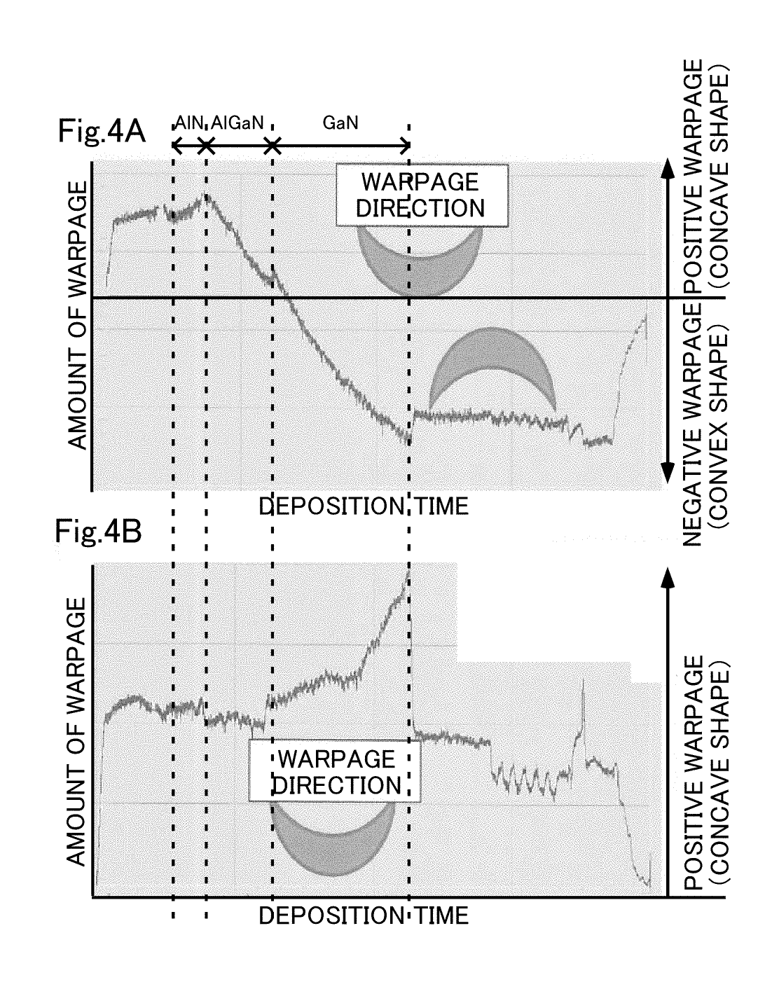

FIGS. 4A and 4B are diagrams illustrating a change in the warpage of a film formed on a silicon substrate by the vapor phase growth apparatus unit 200 according to this embodiment. FIG. 4A is a diagram illustrating a case in which a high-quality film is formed and FIG. 4B is a diagram illustrating a case in which a high-quality film is not formed.

As described above, before a GaN is formed, an AlN film and an AlGaN film are formed on the substrate W. The AlN film and the AlGaN film are buffer layers for compensating for the difference between the lattice constants of Si and GaN.

Since the lattice constant of GaN is greater than the lattice constant of AlGaN, the amount of warpage while the GaN film is being formed is less than the amount of warpage when the AlGaN film is formed and the rate of change in the warpage is a negative value. In addition, when the GaN film is continuously formed, the amount of warpage changes from a positive value to a negative value. FIG. 4A illustrates a change in the warpage.

In FIG. 4B, the amount of warpage when the GaN is formed is a positive value. The rate of change in the warpage when the GaN is formed is a positive value, unlike the case illustrated in FIG. 4A. In the vapor phase growth apparatus unit 200 and the vapor phase growth method according to this embodiment, it is possible to take an appropriate measure, such as a measure to stop the heating of the substrate W, when warpage is not appropriately controlled during deposition as illustrated in FIG. 4B.

Next, the function and effect of this embodiment will be described.

When there is a large difference between the lattice constant of the material of the substrate W and the lattice constant of the material of the film formed on the substrate W, warpage is likely to occur in the substrate W during deposition. When it is difficult to control the warpage, the film is likely to crack, the film is likely to peel off the substrate W, or the substrate W is likely to be broken. When the peeled film or the broken substrate W remains in the reactor, the inside of the reactor is contaminated and an operating ratio is reduced for maintenance. In this embodiment, it is possible to predict the occurrence of a cause of contamination on the basis of the detected warpage and to stop heating. Therefore, the formation of a film by thermal reaction is stopped and it is possible to prevent an increase in the amount of warpage. As a result, it is possible to prevent the contamination of the reactor and to improve the operating ratio of the vapor phase growth apparatus.

For example, when a GaN film is formed on a silicon substrate using process gas including trimethylgallium and ammonia, the lattice mismatch between GaN and Si is 14% and a large amount of warpage occurs. Therefore, in this case, this embodiment is appropriately used.

The embodiments of the invention have been described above with reference to examples. The above-described embodiments are illustrative examples and do not limit the invention. In addition, the components according to each embodiment may be appropriately combined with each other.

For example, in the embodiment, the example in which a gallium nitride (GaN) single-crystal film is formed has been described. However, for example, the invention can be applied to form other group III-V nitride-based semiconductor single-crystal films, such an aluminum nitride (AlN) film, an aluminum gallium nitride (AlGaN) film, and an indium gallium nitride (InGaN) film. Furthermore, the invention can be applied to a group III-V semiconductor such as GaAs.

In addition, the example in which one kind of organic metal, that is, TMG is used has been described. However, two or more kinds of organic metal may be used as a source of a group-III element. In addition, the organic metal may be elements other than the group-III element.

The example in which hydrogen gas (H₂) is used as the carrier gas has been described above. However, nitrogen gas (N₂), argon gas (Ar), helium gas (He), or combinations thereof may be applied as the carrier gas.

The process gas may be, for example, a mixed gas including both a group-III element and a group-V element.

For example, in the embodiment, the vertical single wafer type epitaxial apparatus in which n reactors are used to form films on each substrate has been described as an example. However, the application of the n reactors is not limited to the single-wafer epitaxial apparatus. For example, the invention may be applied to a horizontal epitaxial apparatus or a planetary CVD apparatus that simultaneously forms films on a plurality of wafers which rotate on their own axes while revolving around the apparatus.

In the above-described embodiments, for example, portions which are not directly necessary to describe the invention, such as the configuration of the apparatus or a manufacturing method, are not described. However, the necessary configuration of the apparatus or a necessary manufacturing method can be appropriately selected and used. In addition, all of the vapor phase growth apparatuses and the vapor phase growth methods which include the components according to the invention and whose design can be appropriately changed by those skilled in the art are included in the scope of the invention. The scope of the invention is defined by the scope of the claims and the scope of equivalents thereof.

What is claimed is:

1. A vapor phase growth apparatus comprising:
a reactor;
a a supporter provided in the reactor, a substrate being capable of being placed on the supporter;
a heater heating the substrate;
a warpage measurement device measuring warpage of the substrate;
a controller determining whether the measured warpage or a rate of change in the warpage is greater than a threshold value of the warpage or the rate of change in the warpage and stopping the heater on the basis of a determination result, the threshold value being stored in advance;
a supplier supplying a process gas to the reactor; and
an exhaust exhausting an exhaust gas from the reactor.

2. The vapor phase growth apparatus according to claim 1, wherein a plurality of the reactors is provided, and further comprising:
the supplier supplying a predetermined amount of process gas to each of the reactors;
the exhaust exhausting the exhaust gas from the reactors; and
the controller stopping the heater in any one of the reactors.

3. The vapor phase growth apparatus according to claim 2, wherein the supplier supplies the predetermined amount of process gas to each of the reactors from a unified gas supply source.

4. The vapor phase growth apparatus according to claim 1, wherein the substrate is a silicon substrate, and
the process gas includes trimethylgallium and ammonia.

5. The vapor phase growth apparatus according to claim 1, further comprising:
a shower plate provided in an upper part of the reactor;
a top plate provided above the shower plate;
a first transparent member provided through the shower plate; and
a second transparent member provided through the top plate,
wherein the warpage of the substrate is measured through the first transparent member and the second transparent member.

6. A vapor phase growth method comprising:
placing a substrate on a supporter provided in a reactor;
heating the substrate;
supplying a process gas to the reactor;
measuring warpage of the substrate; and
stopping the heating when the measured warpage or a rate of change in the warpage is greater than a threshold value of the warpage or a threshold value of the rate of change in the warpage, the threshold value being stored in advance.

7. The vapor phase growth method according to claim 6,
wherein the substrate is a silicon substrate, and
the process gas includes trimethylgallium and ammonia.

8. A vapor phase growth method comprising:
placing a substrate on a supporter provided in a reactor;
heating the substrate;
supplying trimethylaluminum, trimethylgallium, and ammonia to the reactor to grow an aluminum gallium nitride film;
supplying trimethylgallium and ammonia to the reactor to grow a gallium nitride film;
measuring warpage of the substrate; and
stopping the heating when the measured warpage or the rate of change in the warpage is greater than a threshold value of the warpage or a threshold value of the rate of change in the warpage, the threshold value being stored in advance.

9. The vapor phase growth method according to claim 8,
wherein, after trimethylaluminum and ammonia are supplied to the reactor to grow an aluminum nitride film, trimethylaluminum, trimethylgallium, and ammonia are supplied to the reactor to grow the aluminum gallium nitride film.

10. The vapor phase growth method according to claim 8,
wherein, after monosilane and ammonia are supplied to the reactor to grow a silicon nitride film, trimethylaluminum and ammonia are supplied to the reactor to grow the aluminum nitride film.

11. The vapor phase growth method according to claim 8,
wherein the substrate is a silicon substrate.
